(19) United States
(12) Patent Application Publication
(10) Pub. No.: US 2025/0123556 A1
(43) Pub. Date: Apr. 17, 2025

(54) Composite Article and Method for Manufacturing a Composite Article

(71) Applicant: Morphotonics Holding B.V., Veldhoven (NL)

(72) Inventors: Jan Matthijs Ter Meulen, Veldhoven (NL); Jules Theodorus Antonius Kierkels, Veldhoven (NL); Leon Willem Veldhuizen, Veldhoven (NL); Bodine Van Der Lubbe, Veldhoven (NL)

(21) Appl. No.: 18/729,282

(22) PCT Filed: Jan. 17, 2023
(86) PCT No.: PCT/NL2023/050018

§ 371 Date: Jul. 16, 2024

(30) Foreign Application Priority Data
Jan. 17, 2022 (EP) 22151745.1
Jul. 8, 2022 (EP) 22183942.6

(51) Int. Cl. G03F 7/00; G03F 7/11

(52) U.S. Cl. CPC G03F 7/0002; G03F 7/11

(57) ABSTRACT

The invention relates to a composite article and a method for manufacturing such article. The composite article includes a substrate, wherein at least part of the substrate includes a texture, and a coating layer, wherein at least part of at least one coating layer is inversed to the texture of the substrate.

### CROSS-REFERENCE TO RELATED APPLICATIONS

This application is the United States national phase of International Patent Application No. PCT/NL2023/050018 filed Jan. 17, 2023, and claims priority to European Patent Application Nos. 22151745.1 filed Jan. 17, 2022 and 22183942.6 filed Jul. 8, 2022, the disclosures of which are hereby incorporated by reference in their entireties.

### BACKGROUND OF THE INVENTION

### Field of the Invention

The invention relates to a composite article. The invention also relates to a method for manufacturing a composite article.

### Description of Related Art

Functional textured layers are surfaces having a texture in the nano- or micrometer range. This can be a random texture, or amongst others diffractive gratings, slanted gratings, blazed gratings, micro-lens arrays, lenticulars, bars, pyramids, prism lines or even a blank surface. The use of functional textured layers on devices such as displays, or solar cells is an important topic. The smart usage of such layers can enhance performance, reduce costs or improve the visual appearance of the product. For example, diffusing layers are used in displays, enabling the use of thinner LED backlight concepts and illuminating the display from the sides. Other new high-tech possibilities are the integration of functional textured layers into solar panels improving their efficiency or integration in organic light-emitting diode (OLED) lighting panels to extract more light.

Functional textured layers can be made via an imprinting process, for example nanoimprinting lithography. A textured stamp can be used to imprint its texture into a (fluid) resin, lacquer or resist layer which is provided upon a substrate. After pressing the stamp on the substrate with resin in between, the textured resin is cured to a solid phase. The curing method can be thermal or by use of radiation such as UV light. With this technique texturing can be carried out with micro- or nano-sized features.

Considering the small scale of the texture, functional textured layers are prone to handling defects. To protect functional textured layers, typically a foil in combination with an adhesive layer is used as protective layer. The combination of the protection foil and the adhesive layer are laminated onto the surface texture which is to be protected, such as a wafer, by means of a lamination or manual pressing process. Foils can also be used without a pressure sensitive adhesive to provide protection. The drawback of these methods is that the risk of air entrapment between the texture and the protective foil is high since the foil and/or the adhesive layer typically do not fully follow the exact texture of the functional textured layer. If air gets entrapped between the foil and the texture, the air might negatively affect the surface structure of the texture. This will typically cause irregularities in the product which is highly undesirable. It is also seen that air causes changes in the surface of the substrate, for example an altered surface roughness. Alternatively, a protective coating could be applied onto the texture of the functional textured layer. However, conventional coatings experience the same drawbacks when it comes to entrapped air compared to foil layers and are in addition to that, more difficult to remove from the functional textured layers, thereby risking damaging the texture or leaving residues on the substrate or texture.

### SUMMARY OF THE INVENTION

It is therefore an object of the present application to provide a solution for at least part of the abovementioned problems, or at least provide an alternative solution for the protection of functional textured layers.

The invention provides thereto a composite article, comprising at least one substrate, wherein at least part of the substrate comprises a texture, and at least one coating layer, wherein at least part of at least one coating layer is provided, and in particular imprinted, upon at least part of the texture of the substrate, such that at least part of the coating layer, in particular the imprinted coating layer, is inversed to the texture of the substrate.

The composite article according to the present invention has several benefits over the prior art. Using a coating layer which is imprinted upon at least part of the texture of the substrate enables the provision of an imprinted coating layer which inversed to the texture of the substrate. In other words, the imprinted coating layer follows the exact texture of substrate. Hence, the imprinted texture of the coating layer is an essentially exact negative image of the texture of the substrate. By using imprinting of the coating layer, it is prevented that air gets entrapped within the texture of the substrate. The coating layer according to the invention is provided upon the texture of the substrate without the enclosure of air. The imprinted coating layer specifies a (negative) mapping of the texture of the substrate in a conformal manner in particular such that all angles between intersecting curves remain, thus leading to a conformal transformation in which angles and scales are preserved. The invention provides a composite article wherein the coating layer is provided upon the texture of the substrate in an air free manner.

At least part of at least one coating layer is in particular imprinted upon at least part of the texture of the substrate, such that at least part of the imprinted coating layer has a texture which is inversed to the texture of the substrate. It may also be said that at least one coating layer comprises an imprinted and/or inversed texture. Hence, the invention also relates to a composite article, comprising at least one substrate, wherein at least part of the substrate comprises a texture, and at least one coating layer provided upon at least part of the texture of the substrate, wherein at least one part of the coating layer comprises an imprinted inversed texture. The coating layer can for example be imprinted via a mechanical imprinting device such as a roll to plate device.

The use of an imprinted coating layer has several benefits over for example applying a coating layer via spin-coating. Spin-coating is a common method for coating a surface, for example for coating (round) wafers, but spin-coating is complex to use for larger surfaces. Rectangular surfaces are also complex to spin-coat. Thirdly, in a spin-coat method it is likely that there is no conformal protection of a textured surface, having deep or steep textures not filled with resin. Spin-coating would typically also require more coating material whereas imprinting enables, minimal application and precise use of coating material without spillage thereof. Lastly, spin-coating is constrained to rigid substrates.

The composite article and method according to the present invention benefit of enabling long term storage, shipping and/or transportation of the article and stacking of a plurality of articles is facilitated. The substrate and in particular the texture thereof is kept clean, and accumulation of dust thereon is prevented. Additionally, harmful radiation or chemicals are kept away from the texture that may damage and/or alter the texture. Further, the composite article is protected from the influence of unwanted climate conditions, such as high humidity which might cause damages by e.g., delamination of the article.

When it is referred to a composite article, also a composite, an assembly or a composite device can be meant. The texture of the substrate can also be referred to as a functional texture, surface texture or surface substrate. The texture can be provided directly in the substrate. It is also conceivable that the substrate comprises at least one functional textured layer of which the texture forms part. It is also imaginable that at least one substrate comprising at least one texture forms a functional textured layer or that the substrate comprising a texture is referred to as a substrate comprising a functional textured layer.

The shape of the substrate typically depends on the intended use. It is for example conceivable that the substrate is substantially rectangular, square, circular and/or a combination thereof. The substrate can also have a free shape. This also applies for the texture, or texture area of the substrate. The substrate is preferably substantially planar. The substrate according to the invention can be relatively large. It is for example conceivable that at least one substrate has a surface area of at least 0.5 m2, at least 1 m2, or at least 2 m2. It is for example possible that the surface is substantially rectangular having a length in the range of 10 cm to 10 m and a width in the range of 10 cm to 5 m.

The coating layer is preferably at least partially fluid upon application onto the substrate, in particular on the texture of the substrate. It is for example conceivable that the coating layer has a viscosity of ranging from 5 cP to 5000 cP, preferably ranging from 5 cP to 500 cP in particular at room temperature. The coating layer may for example also have a viscosity equivalent to the viscosity of water upon application. The coating layer is preferably applied in the form of a liquid or viscous resin onto at least part of the texture of the substrate. Typical application techniques for the resin forming the coating, or coating resin, are printing methods possibly in combination with a lamination and/or imprinting. As printing method for example, ink-jet printing, dispense printing, screen-printing, jet dispensing or any other printing technique known to the person skilled in the art may be used. Further coating processes known to the person skilled in the art may be used such as but not limited to spin-coating, spray-coating and/or slit-coating. For the imprinting step, if applied, a roll-to-roll, a plate-to-plate or a roll-to-plate method could be applied. For the application of the coating resin, either a textured or a non-textured mold or stamp may be used. Said examples can be applied for the method according to the present invention.

At least one coating layer according to the present invention can also be referred to as a protective layer or protective coating layer. At least one coating layer is preferably a removable coating layer. A coating layer that will essentially not cause damage or alterations to the texture of the substrate upon removal can be classified as removable within the context of the present invention. Further, the coating layer is preferably configured to be removed as a whole. Hence, the coating layer is preferably sufficiently strong to be removed without parts of the coating layers staying on the texture of the substrate. A further (chemical) removal aid is not needed to for removal of the coating layer according to the present invention from the substrate.

It is imaginable that the coating layer not only provides a protective function but could also be used for further purposes, after removal from the substrate. Since the coating layer is in particular a copy of the texture of the substrate, the coating layer could also be used to indirectly inspect the quality of the texture of the substrate, without the risk of damaging the primary texture during the inspection. Hence, it is beneficial if the coating layer is configured to be removed from the substrate, and in particular from the texture of the substrate, without being damaged and/or permanently deformed.

The peel force required for the removal of at least one coating layer from the texture of the substrate is preferably lower than the cohesive force of the substrate, for example the cohesive force of the texture of the substrate. It is also conceivable that the peel force required for removal of at least one coating layer from the texture of the substrate is lower than the cohesive force of the coating layer, lower than the cohesive force and/or the adhesive force of any optional additional layer onto which the substrate is attached and/or lower than the cohesive force and/or adhesive force of any optional additional layer onto which the coating layer is attached. It is desired to minimize the peel force that is required to separate the coating layer from the texture of the substrate, while at the same time ensuring a good adhesion between said layers. When it is referred to peel force also the peel strength can be meant. The peel force could for example be determined by a 180 degrees peel test according to the ISO 8510-2 test standard for rigid articles and the ISO 11339 test standard for flexible articles, or an equivalent alternative thereof.

It is for example conceivable that the peel force required for the removal of at least one coating layer from the texture of the substrate is lower than 100 N/m, preferably lower than 50 N/m, more preferably lower than 20 N/m, even more preferably lower than 10 or 3 N/m. It is also conceivable that the peel force is in the range of 1 to 10 N/m or in the range of 2.5 to 7.5 N/m.

At least part of the texture of the substrate preferably has a relatively low surface free energy. Said surface free energy can be indicative for a low peel force of the coating layer. In a possible embodiment, the surface free energy of the texture of the substrate is lower than 70 mN/m, in particular lower than 40 mN/m. It is also imaginable that the surface free energy of the coating layer is lower than 70 mN/m, in particular lower than 40 mN/m. It is also conceivable that the surface free energy of the texture of the substrate is lower than 30 mN/m and in particular lower than 25 mN/m and/or that the surface free energy of the coating layer is lower than 30 mN/m and in particular lower than 25 mN/m. Such values will positively contribute to a low peel force that allows for the easy removal of the coating layer from the texture of the substrate without, or at least minimizing, damaging and/or leaving residues on the texture of the substrate and/or the coating layer. The desired values of the surface free energy could for example be obtained via surface treatment of the substrate, and in particular via surface treatment of the texture of the substrate. It is also conceivable that the surface free energy is controlled by controlling the composition of the coating layer. A low surface free energy is typically obtained by chemical groups which are located on the surface. Typical chemical groups for this purpose are fluorine containing groups such as fluoroalkyl groups, long alkyl groups and alkyl siloxane groups. Hence, it is conceivable that at least part of the texture of the substrate comprises fluoroalkyl groups, long alkyl groups and/or alkyl siloxane groups. At least part of the texture of the substrate can for example be treated with a composition comprising fluoroalkyl groups, long alkyl groups and/or alkyl siloxane groups. It is also conceivable that the coating layer comprises fluoroalkyl groups, long alkyl groups and/or alkyl siloxane groups. It is also conceivable that the substrate and/or the coating layer comprises at least one additive configured to decrease surface free energy materials. Non-limiting example of such additives are perfluoropolyether (PFPE) monomers, perfluorinated monomers, silicone monomers, and/or aliphatic monomers.

Yet a further approach for enhancing the separation of the coating layer from the texture of the substrate is by reducing the interaction between the substrate and the coating layer. This can for example be done by ensuring a low density of strong covalent, ionic, or metallic interface bonds and/or entanglements that are formed between the coating layer and the substrate. In this way, the amount and strength of the interactions between the two interfaces is limited. In a possible embodiment, a preferred interaction between the texture of the substrate and the coating layer is obtained by the texture of the substrate comprising at least one inorganic surface group such as but not limited to SiOx, SiNx, metals and/or metal oxides. Said materials typically do not form strong bonds to organic (e.g., acrylate) surface groups. Following this principle, an embodiment of a composition article comprising a coating layer comprising a UV-cured acrylic resin on a textured glass or silicon substrate would result in successful separation of layers.

It is also conceivable that a relatively low interaction between the texture of the substrate and the coating layer is obtained by passivating and/or deactivating the functional surface groups of the texture via a surface treatment. Such surface treatment can, for example, consist of a deposition step that adds a passivation layer and/or another inactive layer on top of the texture. Another option would be a plasma passivation or deactivation step that passivates a certain amount of the surface groups that otherwise will strongly bond to the coating material. Hence, it is conceivable that the substrate according to the invention comprises a plasma treated texture. It is also conceivable that the substrate and/or coating layer is subjected to an excimer finishing step.

In a possible embodiment of the composite article according to the present invention, the substrate has a Youngs Modulus of less than 4 GPa, preferably less than 3 GPa, more preferably less than 2 GPa. It is also conceivable that the coating layer has a Youngs Modulus of less than 4 GPa, preferably less than 3 GPa, more preferably less than 2 GPa. In yet another embodiment it is conceivable that the composite article according to the invention has a Youngs Modulus of less than 4 GPa, preferably less than 3 GPa, more preferably less than 2 GPa. Alternatively, the substrate may comprise silicon, nickel shim and/or glass with Youngs modulus of about 70 GPa. A carrier layer that is optionally attached to the (removable) coating layer might be attached to a flexible film like polyester (with a Youngs modulus of 4 GPa). The Youngs Modulus is for example measured according to ASTM E111. These embodiments facilitate easy removal of the coating layer in particular without damaging the textures of the substrate and/or coating layer.

In a preferred embodiment, at least part of the substrate comprises an imprinted texture. At least part of the texture can be obtained via an imprinting process, for example nanoimprinting. It is also conceivable that the texture is obtained via a stamping process. It is for example possible that there has been made use of a resin. Typical application techniques for the resin are printing and/or imprinting. As imprinting method, a roll-to-roll, plate-to-plate or roll-to-plate techniques could be used. For the application of the resin, preferably a textured mold or stamp is applied. It is also conceivable that the texture is carved, milled, etched, laser ablated, printed, injection molded, embossed or otherwise machined therein. It is also conceivable that the substrate comprising a texture is configured to be applied in an imprinting process. Hence, the substrate according to the invention can for example be a stamp.

The texture of the substrate is in particular a three-dimensional texture. It is for example possible that at least part of the texture of the substrate comprises a repeated pattern. It is also conceivable that at least part of the texture is a randomized texture. The texture may comprise diffractive gratings, slanted gratings, blazed gratings, micro-lens arrays, lenticulars, pillars, bars, pyramids, prism lines and/or combination thereof. The substrate may comprise at least one active area, in particular wherein said active area comprises the texture.

The depth of the texture can for example be in the nanometer to micrometer scale. It is for example conceivable that at least part of the texture has a dept in the range of 0.1 nm to 500 μm. It is also conceivable that at least part of the texture of the substrate comprises a peak to valley height of at most 1 mm. Preferably, at least part of the texture of the substrate comprises a peak to valley height of at most 10 μm, more preferably at most 5 μm and even more preferably at most 2 μm. However, it is also conceivable that at least part of the texture of the substrate comprises a peak to valley height of at most 100 nm, more preferably at most 50 nm and even more preferably at most 20 or 10 nm.

The specifications of the substrate may depend on the intended use. It is for example conceivable that at least one substrate could comprise glass, metal, polycarbonate and/or polyester. More specifically, it is possible that at least one substrate comprises polyethylene naphthalate (PEN), polyethylene terephthalate (PET) and/or polymethylmethacrylate (PMMA). Preferably, at least part of the substrate is substantially flexible. Alternatively, the substrate can be substantially rigid. The substrate may for example be a rigid plate or block, preferably made of a durable material such as but not limited to glass, silica, quartz, ceramics and/or metal. Non-limiting example of possible metals are steel, copper and/or aluminum. It is also conceivable that the substrate comprises at least one polymeric materials, such as but not limited to at least one thermosetting resin and/or ebonite. It is also conceivable that at least part of the substrate is formed as a sheet. At least one substrate could for example comprise a metal sheet, a plastic sheet, a rubber sheet and/or a glass sheet. It is also conceivable that the substrate is made of substantially the same material as the coating layer. Hence, it is conceivable that the coating layer and the substrate are made of substantially the same material. Any material example as mentioned for the coating layer, can be applied for the substrate too.

At least part of the coating layer is preferably substantially transparent and/or translucent before curing. It is for example possible that at least part of the coating layer is permeable for light, in particular UV light. At least part of the coating layer preferably has a transparency of at least 10%, preferably at least 50%, more preferably at least 90%. At least part of the coating layer preferably has an UV-A transparency, or UV-A permeability, of at least 60%. It is for example conceivable that at least part of the coating layer has an UV-A transparency in the range of 60% to 100%, in particular in the range of 70% to 90%. In a preferred embodiment, at least part of the coating layer has a wavelength cut-off in the range 150 to 400 nm, more preferably in the range of 240 to 380 nm and even more preferably in the range of 280 to 315 nm. The coating layer can be an UV curable or cured coating layer. It is for example possible that at least part of the coating layer is curable when irradiating with a wavelength in the range of 200 nm to 400nm, preferably in the range of 365 to 405 nm. It is also conceivable that at least one coating layer is a thermally curable coating layer.

In an embodiment, at least part of the substrate is preferably substantially transparent and/or translucent. It is for example possible that at least part of the substrate is permeable for light, in particular UV light. At least part of the substrate preferably has a transparency of at least 10%, preferably at least 50%, more preferably at least 90%. At least part of the substrate preferably has a UV-A transparency, or UV-A permeability, of at least 60%. The substrate can comprise a UV curable or cured layer. It is for example possible that at least part of the substrate is curable when irradiating with a wavelength in the range of 300 to 800 nm, preferably in the range of 365 to 405 nm. It is also conceivable that at least part of the substrate is thermally curable.

Preferably, at least part of a bottom surface of the coating layer has a texture which is inverse to the texture of the substrate and/or wherein at least part of an upper surface of the coating layer is substantially flat. Applying the coating layer via an imprinting method enables the provision of a rather uniform coating layer. The coating layer according to the invention can have a substantially uniform thickness. The coating layer according to the present invention is preferably a substantially uniform coating layer. This is beneficial since every minor deviation can affect the texture of the substrate.

At least one coating layer is preferably in direct contact with the texture of the substrate, in particular without the interference of any further medium such as air. As indicated, any medium present upon the substrate or between the substrate and the coating layer can negatively affect the substrate and thus the performance thereof. The provision of a coating layer which form-fittingly engages the texture of the substrate is desired. Preferably, the thickness of the coating layer is substantially uniform. This means in practice that the thickness deviation is at most 20%, preferably at most 10% more preferably at most 5%.

At least one coating layer preferably comprises at least one polymer. It is for example conceivable that at least one coating layer comprises, in particular prior to curing, at least one monomer and/or oligomer, wherein preferably at least one thereof is chosen from the group of: epoxides, thiols, polyvinyl resins, acrylates, methacrylates, polyethers, vinyl ethers, urethane acrylates, polyesters, fluorinated acrylates, fluorinated methacrylates, fluorinated polyethers, siloxanes, siloxane-acrylates and/or blends thereof. It is also conceivable that the coating layer, in particular prior to curing, comprises: a prepolymer composition containing at least one monomer or oligomer component having at least one polymerizable C═C double bond as well as at least one multifunctional monomer component, wherein the multifunctional monomer component contains at least two functional groups selected from the group consisting of (meth)acrylates, methyl (meth)acrylates, vinyl ethers, allyl ethers, propenyl ethers, alkenes, dienes, unsaturated esters, allyl triazines, allyl isocyanates, and N-vinyl amides wherein the monomer or oligomer component having at least one polymerizable double bond is selected from the group consisting of (meth)acrylates, methyl (meth)acrylates, vinyl ethers, allyl ethers, propenyl ethers, alkenes, dienes, unsaturated esters, allyl triazines, allyl isocyanates, and N-vinyl amides, and wherein at least one surface-active anti-adhesive additive selected from the group consisting of alkyl-(meth) acrylates, poly-siloxane (meth) acrylates, (per)fluoroalkyl (meth)acrylates, (per)fluoropolyether (meth)acrylates, alkyl vinyl ethers, polysiloxane vinyl ethers, (per)fluoroalkyl vinyl ethers, and (per)fluoropolyether vinyl ethers. The coating layer, or resin, may further comprise at least one perfluorinated component.

At least one coating layer may comprise at least one additive. It is for example conceivable that at least one additive is an initiator in particular configured for facilitating the curing of the coating layer. At least one coating layer may for example comprise at least one radical, cationic, anionic initiator and/or photo initiator. Non-limiting examples of radical initiators which could be applied are azo compounds such as azobisisobutyronitrile, peroxides such as dibenzoylperoxide or peroxodisulfate, phosphine oxides such as, diphenylphosphine oxide, aromatic ketones such as 1-hydroxy-cyclohexylphenyl-ketone or 2-hydroxy-2-methylpropiophenone, or a norrish type II initiator such as methylbenzoylformate. Possible cationic and anionic initiators are benzenesulfonic acid esters, alkylsulfonium salts or photo base generators such as triphenylsulfonium (cationic), tetrafluoroborate or 2-nitrobenzyl cyclohexylcarbamate (anionic). The use of at least one initiator can further enhance the controllability of the curing process of the coating layer. Depending on the initiator the consolidation may be initiated either thermally or by radiation, e.g., by UV radiation. In an embodiment, the coating layer is completely curable apart from any applied initiator. In a possible embodiment, at least one coating layer, and in particular the coating composition forming the coating layer, comprises at least 95 wt.-%, at least 98 wt.-%, or at least 99 wt.-% of curable material.

In a preferred embodiment, at least one coating layer comprises at least one resin, for example an acrylic resin, preferably comprising at least one siloxane group, epoxide group and/or fluor-organic group. It is for example conceivable that the resin for the coating comprises monomers or oligomers comprising at least one polymerizable epoxide group and/or at least one multifunctional monomer component, wherein the multifunctional monomer component contains at least two functional epoxide groups per molecule. Any mixture of one of these epoxide group containing formulations with the components in the previous paragraph might compose a suitable formulation for the formation of the protective textured layer.

Preferably, at least one coating layer comprises at most 5 wt.-% of solvents. It is also conceivable that at least one coating layer is substantially solvent free. In a possible embodiment, the coating layer comprises at most 1 wt.-% of solvents, at most 2 wt.-% of solvents, at most 3 wt.-% of solvents, at most 4 wt.-% of solvents or at most 5 wt.-% of solvents. In an embodiment, the coating is a pressure-sensitive adhesive which according to the application is produced in situ. Solvents can be classified as fluids that are able to dissolve a reasonable amount of resin and which, at the same time, have a vapor pressure of 30 hPa or more at 25° C.

The composite article, and in particular the coating layer, may further comprise at least one film layer. Such film layer is preferably attached to an upper surface of the coating layer. The film layer, if applied, is preferably attached to a side of the coating layer opposing the side having an (imprinted) texture. The film layer can for example be a polymer film layer, a plastic film layer and/or a rubber film layer. The film layer may also be a foil layer. The film layer may be applied to the coating layer prior to solidification or after solidification. The application method of the film layer can be lamination. The use of a film layer may simplify removal of the coating layer from the substrate. In a possible embodiment, the film layer is adhered to the coating layer by means of an adhesive, preferably a pressure-sensitive adhesive.

In a beneficial embodiment, at least one coating layer comprises multiple coating sublayers. It is for example conceivable that at least one coating layer comprises at least 3 coating sublayers, in particular at least 5 coating sublayers, more in particular at least 7 coating sublayers. It is conceivable that at least two coating sublayers are imprinted coating sublayers. It is also conceivable that each coating sublayer is an imprinted coating sublayer. The composition of each coating sublayer can be similar. It is also possible that at least two coating sublayers have a different composition.

The invention also related to a substrate for use in a composite article according to the present invention. The invention also related to a coating layer for use in a composite article according to the present invention

The invention also relates to a method for manufacturing a composite article, in particular according to the present invention, said method comprising the steps of:
providing at least one substrate, wherein at least part of the substrate comprises a texture;
providing at least one coating composition upon at least part of the texture of the substrate; and
imprinting of the coating composition upon at least part of the texture of the substrate such that an imprinted coating layer is formed which is formed which is inversed to the texture of the substrate.

The method provides for the manufacturing of a composite article according to the present invention. Any of the embodiments described for the substrate and coating layer can be applied. The method may further include the step of enabling solidification of the coating layer. The solidification step can for example be a curing step, such as but not limited to heat and/or UV curing. At least part of the substrate, preferably at least part of the texture, can be subjected to a surface treatment, such as but not limited to a plasma treatment, prior to the coating layer is applied thereupon.

The inventors have provided experiments of composite articles which are discussed hereinafter. Examples of typical peel forces of successful and unsuccessful peels are shown in Table 1. The peel tests were performed according to the ISO 8510-2 test standard using a 180° peel. In these tests, two types of materials were used as coating resins for the substrate and the coating layer:
Material A: a UV-curable acrylate resin
Material B: a UV-curable acrylate resin with a perfluorinated component
   The tested substrate has a texture formed by a pyramid array with 30-μm high features with a base of 50×50 μm. Both the substrate and the coating layer are fabricated on 250-μm thick PET substrates. The substrate was mounted on a rigid carrier in order to perform the peeling test. The coating layers were applied by providing, in particular imprinting of the coating resin, which is solvent-free, on the texture of the substrate, followed-by the lamination of the coating resin on the texture with a plastic foil, and the subsequent UV curing of the coating resin.

The results show that the removal of the coating layer is successful when both the textured substrate and the coating are made of material B (containing the perfluorinated component) or when a surface treatment is performed on material A. In this case, the peel force required to separate the coating from the first three-dimensional layer is low, i.e., below around 25 N/m. Applying the self-assembled passivation layer results in the easiest peel (i.e., the lowest peel force) since in contrast to the atmospheric plasma treatment, the passivation layer does not only neutralize active surface groups, but also reduces the surface free energy to a value lower than 40 mN/m. When the self-assembled passivation layer is not applied onto the substrate, then the combination of materials A and B, for example when the textured article is made of material A and the coating is made of material B, or vice versa, results in a peel force in the medium range of about 25-80 N/m. In this medium range, the peel force required to separate the two layers is sufficiently high for the adhesion between one of the textured layers and its corresponding substrate material to become the weakest link. When both materials consist of material A, then the peel force required to separate the coating from the first three-dimensional layer is high, i.e., above 80 N/m, which results into failing cohesion within the layer stack.

TABLE 1
Peel test results of textured articles and coatings
made of two materials (A and B). In two of the tests,
a surface treatment was performed on the article to
enable a successful separation with the coating.

| | | | | Peel | |
|---|---|---|---|---|---|
| Test | Article | Coating | Article | force | |
| ID | material | material | treatment | (N/m) | Peel result |
| 1 | A | A | None | High | failing cohesion |
| | | | | | of the layer stack |
| 2 | B | A | None | Medium | partly failing |
| | | | | | article/substrate |
| | | | | | adhesion |
| 3 | A | B | None | Medium | partly failing |
| | | | | | coating/substrate |
| | | | | | adhesion |
| 4 | B | B | None | Low | successful peel |
| | | | | | of the coating |
| | | | | | from the article |
| 5 | A | A | atmospheric | Low | successful peel |
| | | | plasma | | of the coating |
| | | | | | from the article |
| 6 | A | A | self-assembled | Low | successful peel |
| | | | passivation | | of the coating |
| | | | layer | | from the article |

### BRIEF DESCRIPTION OF THE DRAWINGS

The terms Fig., Figs., Figure, and Figures are used interchangeably in the specification to refer to the corresponding figures in the drawings.

5 The invention will be further elucidated by means of non-limiting exemplary embodiments illustrated in the following figures, in which:

FIGS. 1a and 1b show a detailed view of a composite article according to the prior art;

FIGS. 2a-2d show possible embodiments of composite articles according to the present invention;

FIGS. 3a and 3b show a further possible embodiment of a composite article according to the present invention; and

FIGS. 4a-4c show 3D images of a substrate and a coating layer according to the present invention.

Within these figures, similar reference numbers correspond to similar or equivalent elements or features.

### DESCRIPTION OF THE INVENTION

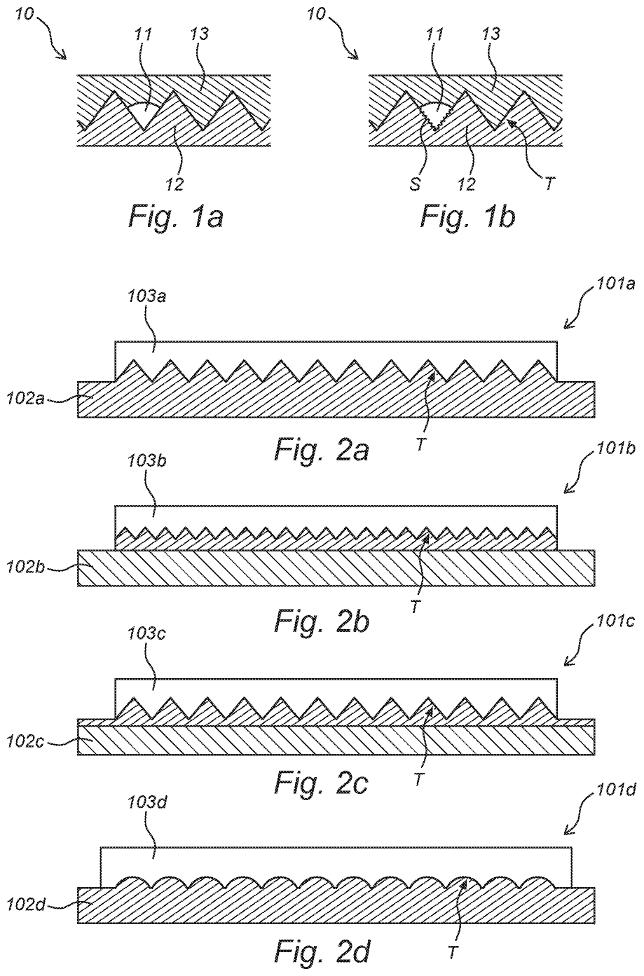

FIGS. 1a and 1b show a detailed view of a drawback of a composite article 10 according to the prior art. The figures show a detailed view of the side view of the composite article 10. The composite article 10 comprises a substrate 12 and a cover layer 13, such as a coating or a foil. The cover layer 13 is applied upon the substrate 12. The figure shows that an air bubble 11 is entrapped between the substrate 12 and the cover layer 13. When this occurs in practice, the air bubble 11 will affect the surface structure S of the substrate 12. The surface structure S of the texture T will roughen and/or change due to the influence of air. This is undesired as it will affect the overall performance of the substrate 12.

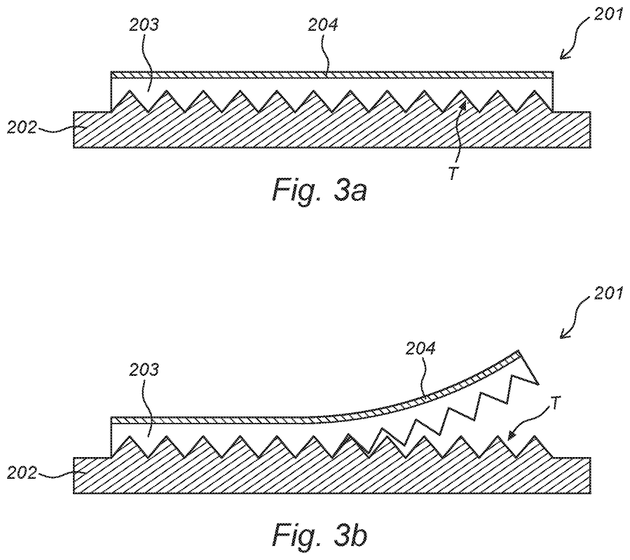

FIGS. 2a-2d show schematic representations of side views of possible embodiments of composite articles 101 according to the present invention. Each figure shows a composite article 101a, 101b, 101c, 101d comprising a substrate 102a, 102b, 102c, 102d and a coating layer 103a, 103b, 103c, 103d. Each substrate 102a, 102b, 102c, 102d comprises a texture T. In the shown non-limiting examples, the textures T have repeating patterns. The design of the textures can depend on the intended use. The scale of the texture is typically in the nanometer scale, up to maximum in the micrometer scale. The coating layer 103a, 103b, 103c, 103d is thereby imprinted upon at least part of the texture T of the substrate 102a, 102b, 102c, 102d. It can be seen that the imprinted coating layer 103a, 103b, 103c, 103d is inversed to the texture T of the substrate 102a, 102b, 102c, 102d. The coating layer 103a, 103b, 103c, 103d of each composite article 101a, 101b, 101c, 101d is removable, which is schematically shown in FIGS. 3a and 3b. FIGS. 2a and 2d show an embodiment wherein the texture T is imprinted in the substrate 102a, 102d. The embodiments of FIGS. 2b and 2c shows embodiments wherein the substrate 102c, 102c comprises a functional textured layer. The texture T is imprinted in said functional textured layer.

FIGS. 3a and 3b show a further possible embodiment of a composite article 201 according to the present invention. The composite article 201 comprises a substrate 202 and a removable coating layer 203, wherein the substrate 203 comprises a texture T. The coating layer 203 further comprises an additional layer 204, in particular a foil layer 204 attached to the coating layer 203. FIG. 3a shows the composite article 201 in an initial state wherein the coating layer 203 is provided upon the texture T of the substrate 202. The coating layer 203 is an imprinted coating layer 203 having an inversed texture with respect to the texture T of the substrate 202. FIG. 3b shows that the coating layer 203 is removed from the substrate 202. The coating layer 203 is basically peeled from the substrate 202. Due to the beneficial characteristics of the coating layer 203 and the substrate 202, the textures of both layers are not affected by the removal. The peel force required for the removal of the coating layer 203 from the texture T of the substrate 202 is thereto typically lower than the cohesive force of the texture T of the substrate 202.

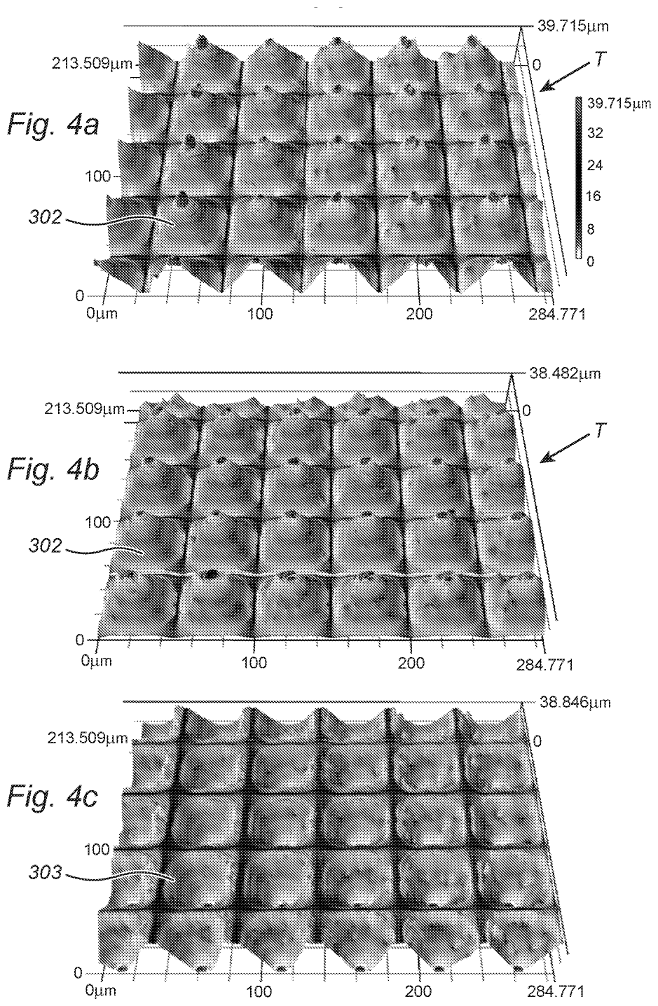

FIGS. 4a-4c show 3D images of a substrate 302 (FIGS. 4a and 4b) and a coating layer 303 (FIG. 4c) according to the present invention. FIGS. 4a and 4b shown the same texture T of the substrate 302 before (FIG. 4a) and after (FIG. 4b) application and removal of the coating layer. FIG. 4c shows the coating layer 303 after removal. It can be seen that no damage or residues are present on the texture T of the substrate 302 and also that the texture of the coating layer 303 is an essentially exact negative image of the texture of the substrate 302. The figures are related to the experimental tests as described in the present application.

It will be clear that the invention is not limited to the exemplary embodiments which are illustrated and described here, but that countless variants are possible within the framework of the attached claims, which will be obvious to the person skilled in the art. In this case, it is conceivable for different inventive concepts and/or technical measures of the above-described variant embodiments to be completely or partly combined without departing from the inventive idea described in the attached claims.

The verb ‘comprise’ and its conjugations as used in this patent document are understood to mean not only ‘comprise’, but to also include the expressions ‘contain’, ‘substantially contain’, ‘formed by’ and conjugations thereof.

1-24. (canceled)

25. A composite article, comprising:
at least one substrate, wherein at least part of the substrate comprises a texture, wherein at least part of the texture comprises a repeated pattern wherein the depth of the texture is in the nanometer to micrometer scale; and
at least one removable coating layer;
wherein at least part of at least one coating layer is imprinted upon at least part of the texture of the substrate, such that at least part of the imprinted coating layer is inversed to the texture of the substrate, wherein the peel force required for removal of the coating layer is lower than 10 N/m.

26. The composite article according to claim 25, wherein the peel force required for removal of at least one coating layer from the texture of the substrate is lower than the cohesive force of the substrate.

27. The composite article according to claim 25, wherein the peel force required for removal of the coating layer is lower than 7.5 N/m or lower than 3 N/m.

28. The composite article according to claim 25, wherein the surface free energy of the texture of the substrate is lower than 70 mN/m or lower than 40 mN/m or lower than 25 mN/m.

29. The composite article according to claim 25, wherein the surface free energy of the coating layer is lower than 70 mN/m or lower than 40 mN/m or lower than 25 mN/m.

30. The composite article according to claim 25, wherein at least one coating layer comprises fluoroalkyl groups, long alkyl groups and/or alkyl siloxane groups.

31. The composite article according to claim 25, wherein at least one coating layer has a Youngs Modulus of less than 4 GPa and/or wherein at least one substrate has a Youngs Modulus of less than 4 GPa.

32. The composite article according to claim 25, wherein at least part of the substrate comprises an imprinted texture.

33. The composite article according to claim 25, wherein at least part of the texture of the substrate comprises a peak to valley height of at most 10 μm or at most 5 μm or at most 2 μm.

34. The composite article according to claim 25, wherein at least one substrate comprises glass, metal, polycarbonate and/or polyester.

35. The composite article according to claim 25, wherein at least part of a bottom surface of the coating layer has a texture which is inverse to the texture of the substrate and wherein at least part of an upper surface of the coating layer is substantially flat.

36. The composite article according to claim 25, wherein at least one coating layer is in direct contact with the texture of the substrate and/or wherein the thickness of the coating layer is substantially uniform.

37. The composite article according to claim 25, wherein at least one coating layer comprises at least one monomeric, oligomeric or polymeric monomer and/or oligomer at least prior to curing.

38. The composite article according to claim 25, wherein at least one coating layer comprises at least one additive such as at least one initiator.

39. The composite article according to claim 25, wherein at least one coating layer comprises at least one acrylic resin comprising at least one siloxane group, epoxide group and/or fluor-organic group.

40. The composite article according to claim 25, wherein at least one coating layer comprises at most 5 wt.-% of solvents.

41. The composite article according to claim 35, comprising at least one film layer attached to the upper surface of the coating layer, wherein the film layer is chosen from the group of: a polymer film layer, a plastic film layer, a rubber film layer and/or a foil layer.

42. The composite article according to claim 25, wherein at least one coating layer comprises multiple coating sublayers.

43. A method for manufacturing a composite article, said method comprising the steps of:
providing at least one substrate, wherein at least part of the substrate comprises a texture, wherein at least part of the texture comprises a repeated pattern wherein the depth of the texture is in the nanometer to micrometer scale;
providing at least one coating composition upon at least part of the texture of the substrate;
imprinting the coating composition upon at least part of the texture of the substrate such that an imprinted coating layer is formed which is inversed to the texture of the substrate, wherein the coating layer is a removable coating layer and wherein the peel force required for removal of the coating layer is lower than 10 N/m.

44. The method according to claim 43, comprising the step of enabling solidification of the coating layer.
